(19) United States
(12) Patent Application Publication
(10) Pub. No.: US 2010/0108119 A1
(43) Pub. Date: May 6, 2010

(54) INTEGRATED BYPASS DIODE ASSEMBLIES FOR BACK CONTACT SOLAR CELLS AND MODULES

(75) Inventors: JAMES GEE, Albuquerque, NM (US); DAVID H. MEAKIN, Albuquerque, NM (US); FARES BAGH, Austin, TX (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/620,547

(22) Filed: Nov. 17, 2009

Related U.S. Application Data
(60) Provisional application No. 61/115,280, filed on Nov. 17, 2008.
(60) Provisional application No. 61/116,093, filed on Nov. 19, 2008.

(51) Int. Cl. H01L 31/042; H01L 31/00

(52) U.S. Cl. 136/244; 136/252; 136/259

(57) ABSTRACT

The present invention comprises methods for manufacturing solar cell modules having improved fault tolerance and the ability to maximize module power output in response to non-optimal operation of one or more solar cells in the module. To improve the fault tolerance, the individual solar cells may each have a bypass diode coupled thereto to that when a single solar cell faults, only the faulted solar cell is affected. In one embodiment, a transistor may be used to improve the fault tolerance of a solar cell module.

### CROSS-REFERENCE TO RELATED APPLICATIONS

This application claims benefit of U.S. Provisional Patent Application Ser. No. 61/115,280, filed Nov. 17, 2008, and U.S. Provisional Patent Application Ser. No. 61/116,093, filed Nov. 19, 2008, both of which are herein incorporated by reference.

### BACKGROUND OF THE INVENTION

1. Field of the Invention

The present invention comprises methods for manufacturing solar cell modules having improved fault tolerance and the ability to maximize module power output in response to non-optimal operation of one or more solar cells in the module or to non-optimal operation conditions such as shading.

2. Description of the Related Art

Photovoltaic (PV) modules consist of solar cells that are electrically connected in various series and parallel configurations and encapsulated for environmental protection. Usually, the solar cells are electrically connected in series. A series rather than parallel electrical circuit produces a higher voltage and lower current for a given module power, which is advantageous for integration into solar systems.

All the solar cells in a series-connected electrical circuit have the same current. This implies that current, and therefore the power output, of a “string” of solar cells in electrical series will be limited by the solar cell with the lowest current. Manufacturers will typically sort the solar cells by current in order to maximize the electrical performance in the module. Nevertheless, several factors can cause the current of the solar cells to be mismatched in a module and thereby reduce the module performance in the system. For example:
cells may crack through the assembly process or in fielded systems;
the electrical interconnection to some cells may degrade or fail over time in fielded systems;
the module may become optically degraded in inhomogeneous manner; and/or
portions of the module may be shaded at different times of the day in fielded systems.

Solar cells with highly mismatched currents in series circuits also can introduce another field degradation problem due to overheating of the solar cell with the lowest current. This condition is known as hot spotting. The issue occurs because the solar cell with the low current will be driven into reverse bias and eventually into breakdown by the other current sources (i.e., solar cells) in the electrical circuit. As is well known in the art, a bypass diode can be included across a “string” of solar cells to minimize the reverse bias across a cell to the maximum voltage of the solar cell string. The maximum voltage generated by the string must be less than the reverse breakdown voltage of any solar cell in the circuit in order for the bypass diode to provide any protection. Therefore, the solar cells must also be sorted by maximum reverse breakdown voltage (V_{br}) as well as by current. V_{br} is frequently lower for solar cells using lower grade—and therefore generally less expensive—semiconductor materials, thus such solar cells may require module circuits with fewer cells per string and additional bypass diodes.

As an example, a typical PV module using crystalline-silicon solar cells may have sixty cells 15 arranged into three strings of twenty cells each, with bypass diode 10 across each string (FIG. 1). The maximum reverse bias of an individual solar cell with limited current generation in a bypassed string of twenty cells is roughly 10V (i.e., about 0.5V per cell). In the most extreme case, the output of the entire string is lost if the electrical interconnect completely fails, or if one individual solar cell is completely shaded, in the string. In the pictured example, the bypass diode shunts the current around the 20-cell string and the voltage of the module is reduced by one third; i.e., one out of three of the 20-cell strings. Thus, although current solar cell circuits with bypass diodes across a limited number of solar cell strings minimize the possibility of damage to the PV module, they still allow for a large performance degradation of the PV module. In the above example, up to one third of the module output could be lost due to fault in a single solar cell.

There is also considerable interest in integrating power conversion electronics on each PV module. The power conversion electronics may perform a dc-ac conversion (micro-inverter) or a dc-dc conversion to the array voltage. In either case, the power electronics attempts to maximize the power generated from each module and minimize the effect of the module performance on other modules in the array. Power converters typically require a minimum voltage for operation, and have zero output when the input voltage is below this minimum operation voltage. In the previous example, the PV module voltage is reduced by one third to around 20V (two strings at 10V each) in a 6×10 module with a single cell is shaded. The output of this module with a module-integrated power converter would be reduced to zero if the PV module voltage is below the minimum input voltage required by the converter. Hence, modules with integrated power converters could have greatly increased sensitivity to fault conditions. Thus it is desirable to increase the sensitivity to fault conditions for modules with integrated power sources.

### SUMMARY OF THE INVENTION

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

In one embodiment, photovoltaic module is disclosed. The photovoltaic module includes at least one substrate having at least one via formed therethrough and one or more circuits coupled to the at least one substrate. The circuit has a positive portion coupled to the first substrate and a negative portion coupled to the at least one substrate. The photovoltaic module also includes one or more bypass diodes coupled between the positive position and the negative portion. The photovoltaic module also includes one or more solar cells coupled to the one or more circuits.

In another embodiment, a photovoltaic module is disclosed. The photovoltaic module includes at least one substrate having at least one via formed therethrough and one or more circuits coupled to the at least one substrate. The circuit has a positive portion coupled to the at least one substrate and a negative portion coupled to the at least one substrate. The photovoltaic module includes one or more active bypass elements coupled between the positive position and the negative portion and one or more solar cells coupled to the one or more circuits.

In another embodiment, a dynamic solar cell network is disclosed. The network includes a switchboard and a plurality of solar cells individually coupled to the switchboard. The switchboard is capable of dynamically optimizing power generation of the dynamic network based on the performance of each solar cell of the plurality of solar cells to optimize power generation of the plurality of solar cells.

In another embodiment, a photovoltaic module is disclosed. The module includes a back contact solar cell, a first positive polarity contact coupled with the solar cell and a first negative polarity contact coupled with the solar cell. The module also includes a bypass diode, a second positive polarity contact coupled with the bypass diode and the first negative polarity contact and a second negative polarity contact coupled with the bypass diode and the first positive polarity contact.

### BRIEF DESCRIPTION OF THE DRAWINGS

The accompanying drawings, which are incorporated into and form a part of the specification, illustrate several embodiments of the present invention and, together with a description, serve to explain the principles of the invention. The drawings are only for the purpose of illustrating one or more particular embodiments of the invention and are not to be construed as limiting the invention. In the drawings:

FIG. 1 is an example of an equivalent circuit of a photovoltaic module with sixty cells arranged into three strings, each string comprising twenty cells and a bypass diode;

FIG. 2 is an embodiment of the present invention showing an equivalent circuit of a photovoltaic module comprising a bypass diode across each solar cell;

FIG. 3A shows module I-V performance curves for a conventional module (having three strings of 24 solar cells, each string with a bypass diode) both unshaded and with one cell shaded;

FIG. 3B shows module I-V performance curves for a fault tolerant module in accordance with an embodiment of the present invention, both unshaded and with one cell shaded, with the shaded cell having its own bypass diode;

FIG. 4 is an embodiment of the present invention showing an equivalent circuit of a photovoltaic module comprising active bypass functions; and

FIG. 5 is an embodiment of the present invention showing an equivalent circuit of a photovoltaic module where the power output of each solar cell is routed to a central switchboard comprising an intelligent controller.

FIG. 6A is a plan view illustration of bypass diode placement on a back-contact silicon solar cell;

FIG. 6B is a cross section of a bypass diode disposed on a back contact solar cell taken along center line A-A′ of FIG. 6B;

FIG. 7A is a schematic cross sectional view of a solar cell having an embedded bypass circuit according to one embodiment; and

FIG. 7B is a schematic top view of FIG. 7A with the solar cell removed for clarity.

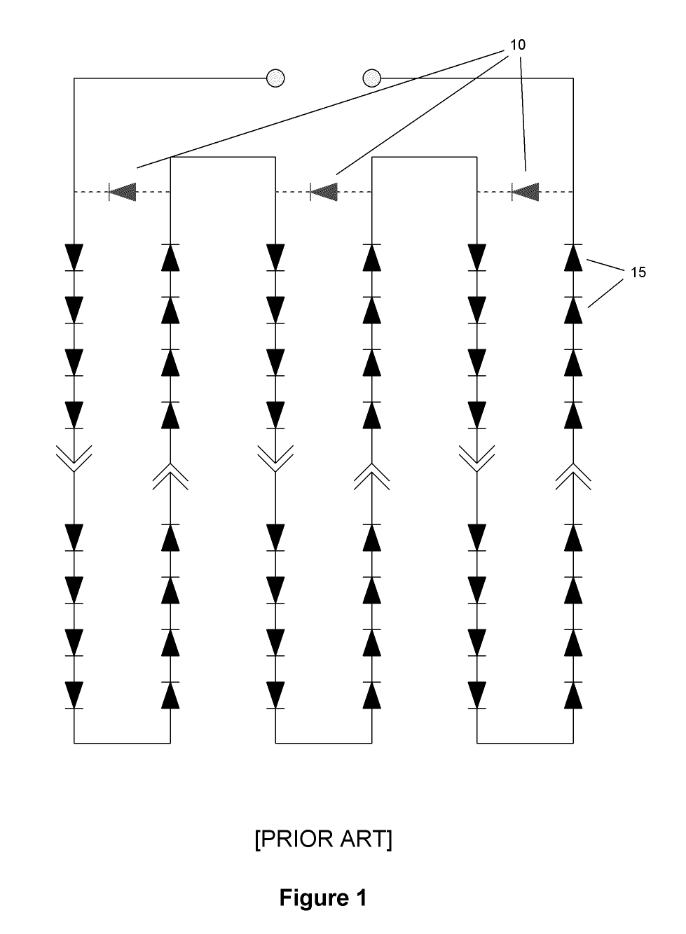

### DETAILED DESCRIPTION

The present invention improves the performance of a module by minimizing the impact of non-optimal operating conditions or degradation in individual solar cells on PV module output through the use of novel solar cell circuit geometries enabled by integration with the module assembly technology. The use of back-contact cells and a module backsheet with an electrical circuit (“flexible circuit”) wherein the module electrical circuit and the module lamination are performed in a single step are described in commonly owned U.S. patent application Ser. No. 11/963,841, entitled “Interconnect Technologies for Back Contact Solar Cells and Modules”. Flexible circuits may comprise multiple layers with conductive paths between layers that can enable complex circuit geometries. The simplest multi-level flexible circuit has an electrical circuit on both surfaces of the substrates. Alternatively, dielectric layers can be used for isolation between conductive layers.

Most crystalline-silicon solar cells are assembled into an electrical circuit with flat Cu ribbon wires between solar cells. A flexible circuit allows for much more complicated geometries than those that can be easily achieved with discrete wires. Rather than just connecting adjacent solar cells in series, the flexible circuit can allow for integration of additional electrical components, for more arbitrary electrical circuit layouts, and for addition of control and sense lines in addition to the power distribution. These components can include additional bypass diodes and/or dynamic switching to enable true maximization of module performance at the cell level. Two approaches—passive and dynamic—are described that take advantage of the easier integration available with flexible circuits for improving the performance of a photovoltaic module.

### Passive Bypass

Bypass diodes can be integrated with the flexible circuit. The flexible circuit can use conductive vias through the circuit's substrate so that the bypass diode is mounted on the opposite surface from the solar cell. This type of integration prevents any loss of area in the module, thereby maintaining the energy conversion efficiency of the module (power per unit area). A flat-pack diode can be used that has a flat profile and integrates into the laminate easily. The diode could also be a bare semiconductor device similar to a solar cell; i.e., including no packaging for the diode itself. Alternatively, the bypass diode can use thin-film semiconductors that are deposited directly on the substrate for the flexible circuit. Further, a plurality of diodes can be placed in parallel with each cell to minimize the current requirements of each diode and distribute the thermal load of the bypass diodes in operation.

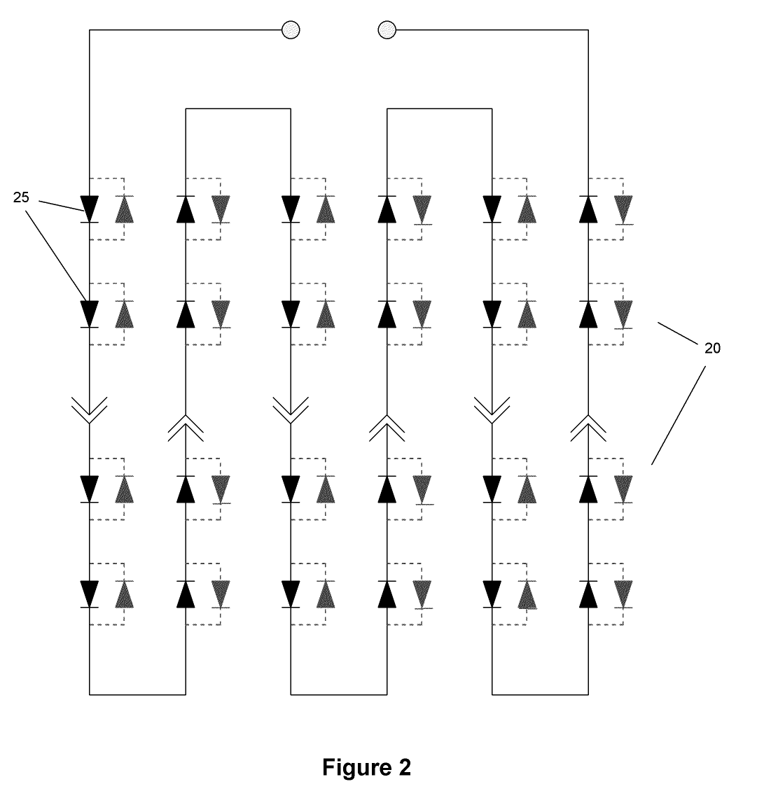

The number of solar cells per bypass diode can more easily be reduced when using a flexible circuit than in electrical circuits with conventional module assembly due to a greater number or possible circuit layouts of the flexible circuit. The maximum loss due to a complete fault is now only the reduced number of cells in the string, which reduces the power loss in the module. As shown in the equivalent circuit of FIG. 2, a bypass diode 20 can be integrated across each solar cell 25, thereby minimizing the power loss due to a fault (such as shading or cracking) in a single cell to only that cell. This also reduces the maximum reverse bias for the damaged cell to just the forward bias of the bypass diode (typically less than 1V), which significantly reduces both power dissipation in the solar cell and any degradation of the solar cell itself or of the packaging around the solar cell.

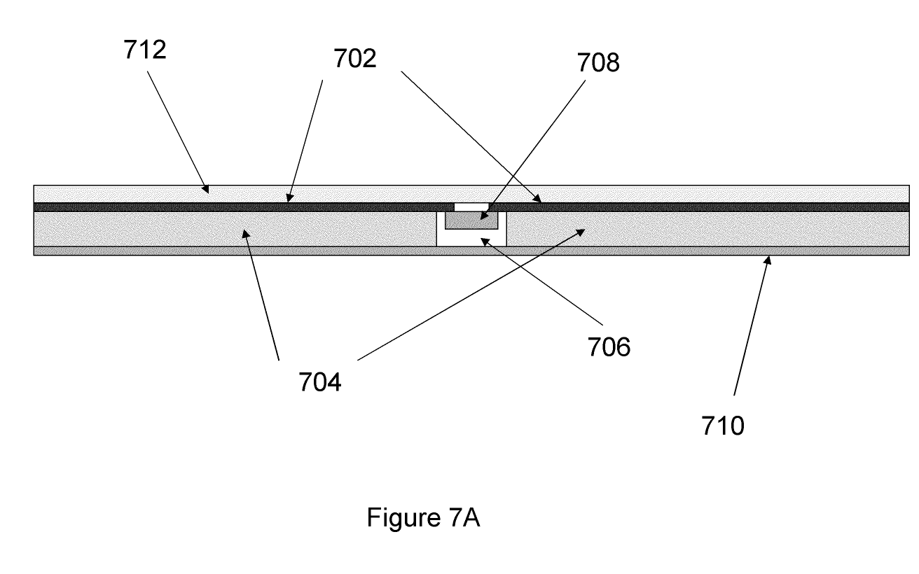

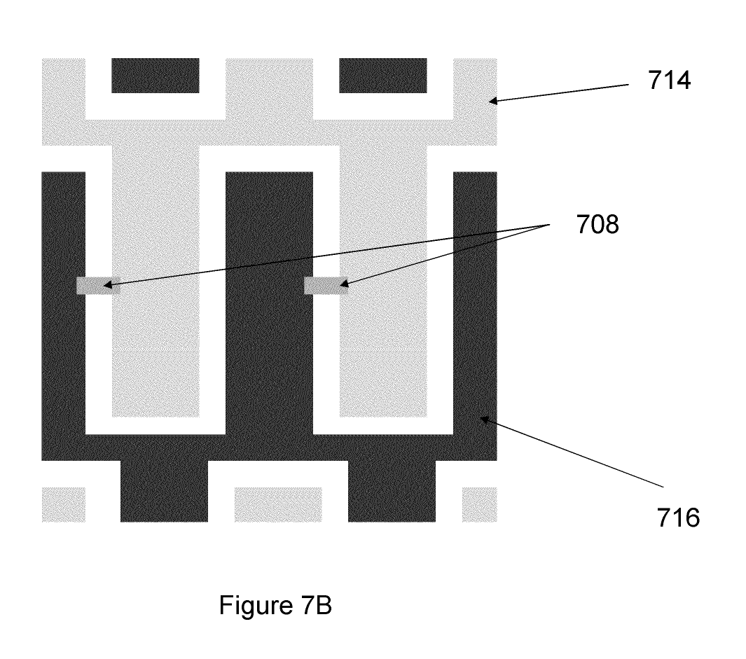

An example of a flexible circuit with bypass diode integrated is provided in plan and cross section view in FIGS. 7A and 7B. The electrical conductors that form the circuit 702 are on a flexible substrate 704. The positive circuit 714 and negative circuit 716 are shown in FIG. 7B. The electrical conductors connect to the negative and positive terminals on the back-contact solar cell 712. The substrate material is typically a polyester (PET) or polyimide—although other polymeric materials could be used. The substrate has an opening 706 that exposes the circuit elements that contact the negative and positive polarities of the solar cell. A bypass diode can then be electrically attached to the circuit elements in the via 706. An outer protection layer 710is adhesively bonded over the rear surface with roll-to-roll processing. A typical outer layer material for photovoltaic modules is polyvinyl fluoride. The flexible-circuit construction could include a moisture barrier layer somewhere between the outer layer and the solar cell circuit. The inclusion of electrical components within the flexible circuit construction is an example of embedded passive components that is common in printed wiring board and flexible circuit industries.

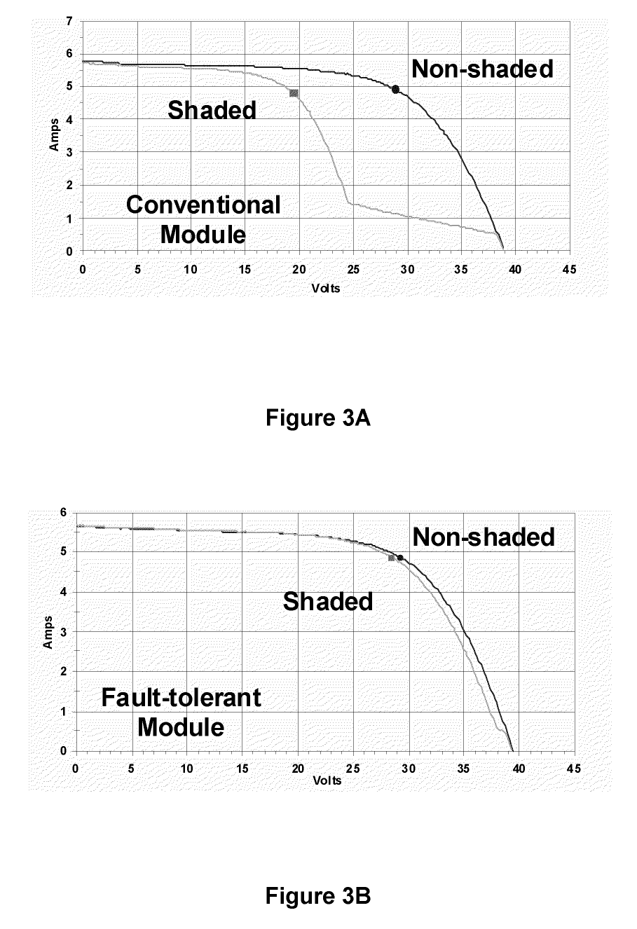

The performance improvement for such a configuration is shown in FIG. 3B. A photovoltaic module was constructed with additional leads so that a bypass diode could either be added or omitted across an individual solar cell. The module comprised 72 125-mm cells with the usual configuration of three bypass diodes across three strings of solar cells. The module light-IV curve was measured with the module unshaded and with a single cell shaded (FIG. 3A). As expected, nearly one third of the output of the module was lost. FIG. 3B shows the same experiment but with a module in which the shaded cell had its own bypass diode. In this case, the output was only reduced by roughly a single solar cell output.

### Active Bypass

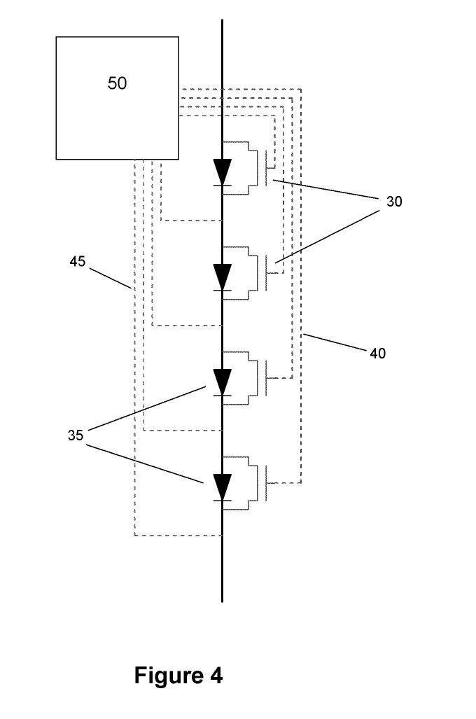

The bypass function can be implemented with active devices rather than with a passive bypass diode. An example of an active device is a semiconductor switch (i.e., transistor) that can be switched ON to shunt the cell with the fault. An active bypass flexible circuit preferably comprises additional traces for sensing voltage, for actuation of additional electronic devices, and for transistor mounting; one embodiment is shown in the equivalent circuit of FIG. 4. The voltage of sense lines 45 are preferably monitored by intelligent controller 50, which interprets the information and then activates as necessary bypass transistors 30 via control lines 40. These additional circuit lines can either be on the same level as the circuit for solar cells 35, or they can be on a separate level. Bypass transistors 30 preferably have a low profile so that they can be mounted on the opposite surface of the flexible circuit. Alternatively, the transistors can be fabricated using thin-film deposited semiconductor layers on the flexible circuit. Intelligent controller 50 can use various software algorithms for determining when to open and close various bypass transistors or switches. The controller may optionally also either accept commands from, or provide information to, a central system controller.

### Dynamic Network

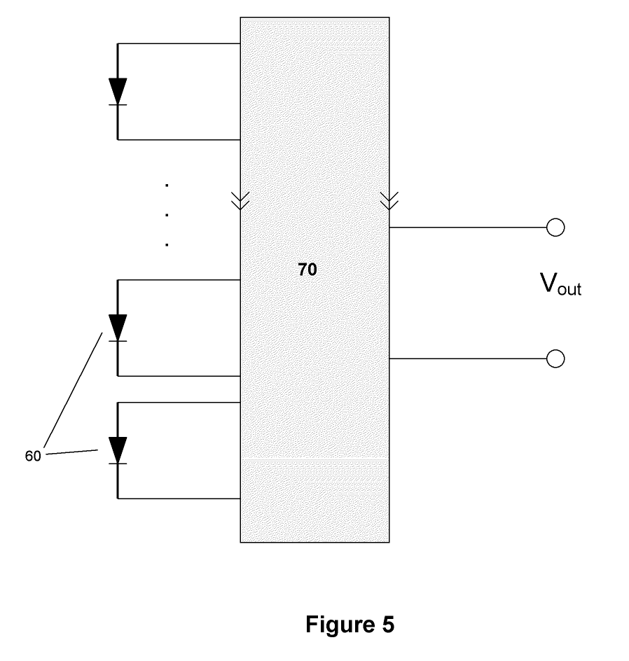

In another embodiment of the present invention, shown in FIG. 5, each solar cell 60 can be individually addressed to intelligent controller and switching network or switchboard 70. The switching network is electrically equivalent to a multiplexer. This may optionally be utilized with any of the embodiments described herein, or any currently existing module circuits. In this embodiment the electrical circuit can be dynamically changed based on the performance of the individual solar cells to optimize the power generation of the solar cells. The dynamic circuit may be incorporated into the dc-ac conversion process. The advantage of such a circuit is that it can minimize power loss when there are multiple faults in the module. For example, in the above embodiments, if two cells are shaded so that each produces half the current of the rest of the solar cells in the module, the entire output of each shaded solar cell could be shunted with a bypass diode or transistor, the resulting power loss equivalent to two solar cells. However, with a dynamic network, the outputs of the two shaded cells are preferably added in parallel to achieve the equivalent power of a single non-shaded cell. The resulting reduction of power is thus the equivalent of only one solar cell; the power reduction has thus been reduced by 50%. As described previously, the intelligent controller can use various algorithms for maximizing performance and can communicate with a central system controller for additional functionality.

### Back-Contact Solar Cell Comprising Integrated Bypass Diode

Conventional crystalline-silicon solar cells have positive and negative polarity contacts on opposite surfaces. It is difficult to integrate a bypass diode with conventional cells because electrical contacts must be made to opposite surfaces of the cell. In contrast, back-contact solar cells have both the positive- and negative-polarity contacts on the rear surface. The advantages of back-contact solar cells include: higher efficiencies due to reduced or eliminated optical losses due to a current-collection grid on the front surface, simpler module assembly methods due to coplanar contacts, reduced stress in the module package due to a more planar geometry, and improved aesthetics due to a more uniform appearance. A number of different approaches (for example, emitter wrap-through, metallization wrap-through, or back junction) have been described for back-contact cell configurations.

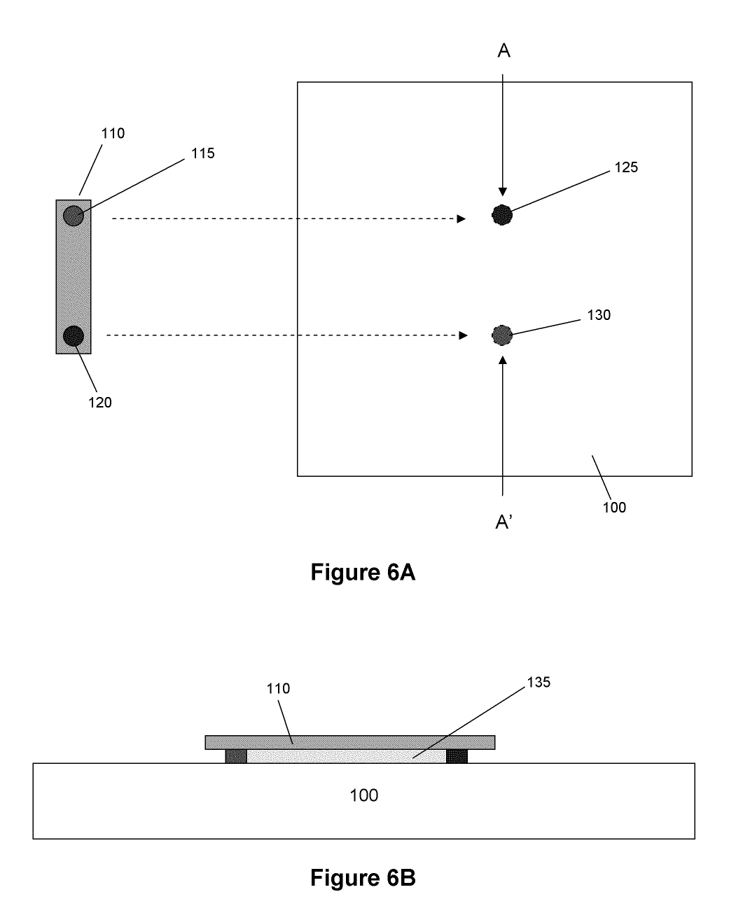

Because both the negative- and positive-polarity contacts are on the same surface of a back-contact solar cell, a bypass diode can be assembled directly onto the cell. The solar cells and diodes are preferably fabricated and tested separately. The diode is then preferably assembled directly onto the solar cell, as shown in FIGS. 6A and 6B. Back-contact solar cell 100 preferably comprises contacting points for integration with the bypass diode, such as positive-polarity contact 125 and negative-polarity contact 130. Although any diode may be used, the simplest diode for integration is a bare semiconductor die where the diode has both polarity contacts on the same surface. These contacts can be designed to align to the contacts on the solar cell similar to surface mount technology techniques. In FIGS. 6A and 6B, bypass diode 110 comprises, on the same surface, positive-polarity contact 120 for attachment to the cell's negative-polarity contact 130 and negative-polarity contact 115 for attachment to the cell's positive-polarity contact 125. Conventional packaged diodes (flat-pack style) may alternatively be used. The assembly operation comprises electrically attaching the diode, preferably via soldering or conductive adhesive, to the solar cell and, optionally, disposing encapsulation or underfill 135 between the solar cell and diode, e.g. similar to the die-attach underfill process. This finished assembly of a solar cell with an integrated bypass diode is then assembled into a photovoltaic module.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference.

1. A photovoltaic module, comprising:
at least one substrate having at least one via formed therethrough;
one or more circuits coupled to the at least one substrate, the circuit having a positive portion coupled to the at least one substrate and a negative portion coupled to the at least one substrate;
one or more bypass diodes coupled between the positive portion and the negative portion; and
one or more solar cells coupled to the one or more circuits.

2. The photovoltaic module of claim 1, wherein the one or more bypass diodes comprises a plurality of bypass diodes coupled to each of the one or more solar cells.

3. The photovoltaic module of claim 2, wherein the one or more solar cells comprise plurality of solar cells connected in series.

4. The photovoltaic module of claim 1, wherein the one or more solar cells comprises a plurality of solar cells and each one or more solar cell has a corresponding bypass diode or plurality of bypass diodes.

5. The photovoltaic module of claim 1, wherein the one or more solar cells comprises plurality of solar cells connected in parallel.

6. The photovoltaic module of claim 1, further comprising a flexible backplane coupled to the at least one substrate.

7. The photovoltaic module of claim 1, wherein the one or more bypass diodes are embedded within the at least one via.

8. The photovoltaic module of claim 1, wherein the at least one via comprises a plurality of vias, wherein at least one first via corresponds to a negative polarity and at least one second via corresponds to a positive polarity and wherein one or more bypass diodes are disposed over the at least one first via and at least one second via.

9. A photovoltaic module, comprising:
at least one substrate having at least one via formed therethrough;
one or more circuits coupled to the at least one substrate, the circuit having a positive portion coupled to the at least substrate and a negative portion coupled to the at least one substrate;
one or more active bypass elements coupled between the positive portion and the negative portion; and
one or more solar cells coupled to the one or more circuits.

10. The photovoltaic module of claim 9, wherein the one or more active bypass elements comprises a transistor.

11. The photovoltaic module of claim 10, wherein the at least one via comprises a plurality of vias, wherein at least one first via corresponds to a negative polarity and at least one second via corresponds to a positive polarity and wherein one or more active bypass elements are disposed over the at least one first via and at least one second via.

12. The photovoltaic module of claim 10, wherein the one or more active bypass elements are embedded within the at least one via.

13. The photovoltaic module of claim 10, further comprising:
a microcontroller;
one or more sense lines coupled to the microcontroller and a location between adjacent solar cells; and
one or more control lines coupled to the microcontroller and a gate electrode of the transistor.

14. The photovoltaic module of claim 9, wherein the one or more active bypass elements comprises a plurality of active bypass elements coupled to each of the one or more solar cells.

15. The photovoltaic module of claim 14, wherein the plurality of solar cells are connected in series.

16. The photovoltaic module of claim 9, wherein the one or more solar cells comprises a plurality of solar cells and each one or more solar cell has a corresponding active bypass element or plurality of active bypass elements.

17. A dynamic solar cell network, comprising:
a switchboard;
a plurality of solar cells individually coupled to the switchboard, wherein the switchboard is capable of dynamically optimizing power generation of the dynamic network based on the performance of each solar cell of the plurality of solar cells to optimize power generation of the plurality of solar cells.

18. The dynamic solar cell network of claim 17, further comprising at least one bypass diode or at least one transistor coupled to each of the plurality of solar cells.

19. (canceled)

20. (canceled)
